(19) United States
(12) Patent Application Publication
(10) Pub. No.: US 2016/0276356 A1
(43) Pub. Date: Sep. 22, 2016

(54) SEMICONDUCTOR MEMORY DEVICE

(71) Applicant: Kabushiki Kaisha Toshiba, Minato-ku (JP)

(72) Inventor: Yukihiro UTSUNO, Yokohama (JP)

(73) Assignee: Kabushiki Kaisha Toshiba, Minato-ku (JP)

(21) Appl. No.: 14/945,812

(22) Filed: Nov. 19, 2015

Related U.S. Application Data
(60) Provisional application No. 62/134,867, filed on Mar. 18, 2015.

(51) Int. Cl. H01L 27/115; H01L 21/265; H01L 21/308

(52) U.S. Cl. CPC H01L 27/11521; H01L 21/3081; H01L 21/26513

(57) ABSTRACT

A semiconductor memory device of the embodiments includes a first conductivity type semiconductor layer extending in a first direction and including a plurality of projecting regions on the surface thereof, a first insulating film provided on the projecting regions, a charge storage layer provided on the first insulating film, a second insulating film provided on the charge storage layer, and a control gate provided on the second insulating film.

### CROSS-REFERENCE TO RELATED APPLICATION

This application is based upon and claims the benefit of priority from U.S. Provisional Application No. 62/134,867, filed on Mar. 18, 2015, the entire contents of which are incorporated herein by reference.

### FIELD

Embodiments described herein relate generally to a semiconductor memory device.

### BACKGROUND

A memory cell has been scaled down in order to increase a capacity of the semiconductor memory device. In accordance with the scaling-down of the memory cell, a channel length of a memory cell transistor becomes short. When the channel length of the memory cell transistor becomes short, a short channel effect of the memory cell transistor becomes large and a threshold voltage variation of the memory cell transistor becomes large. The large threshold voltage variation of the memory cell transistor causes various failures such as read error of cell data.

### BRIEF DESCRIPTION OF THE DRAWINGS

FIG. 1 is a schematic cross sectional view of a semiconductor memory device according to a first embodiment;

FIG. 2 is a circuit diagram of a memory cell array of the semiconductor memory device according to the first embodiment;

FIG. 3 is a schematic cross sectional view of a semiconductor memory device according to a comparative embodiment;

FIG. 4 is a schematic cross sectional view of a semiconductor memory device according to a second embodiment;

FIG. 5 is a schematic cross sectional view of a semiconductor memory device according to a third embodiment;

FIG. 6 is a schematic cross sectional view of a semiconductor memory device during a manufacturing process in a manufacturing method according to a fourth embodiment;

FIG. 7 is a schematic cross sectional view of the semiconductor memory device during the manufacturing process in the manufacturing method according to the fourth embodiment;

FIG. 8 is a schematic cross sectional view of the semiconductor memory device during the manufacturing process in the manufacturing method according to the fourth embodiment;

FIG. 9 is a schematic cross sectional view of a semiconductor memory device during a manufacturing process in a manufacturing method according to a fifth embodiment;

FIG. 10 is a schematic cross sectional view of the semiconductor memory device during the manufacturing process in the manufacturing method according to the fifth embodiment;

FIG. 11 is a schematic cross sectional view of the semiconductor memory device during the manufacturing process in the manufacturing method according to the fifth embodiment;

FIG. 12 is a schematic cross sectional view of a semiconductor memory device during a manufacturing process in a manufacturing method according to a sixth embodiment;

FIG. 13 is a schematic cross sectional view of the semiconductor memory device during the manufacturing process in the manufacturing method according to the sixth embodiment; and

FIG. 14 is a schematic cross sectional view of the semiconductor memory device during the manufacturing process in the manufacturing method according to the sixth embodiment.

### DETAILED DESCRIPTION

Hereinafter, embodiments will be described with reference to the drawings.

### First Embodiment

A semiconductor memory device of the present embodiment includes a first conductivity type semiconductor layer, a first insulating film, a charge storage layer, a second insulating film, and a control gate electrode. The first conductivity type semiconductor layer extends in a first direction and includes a plurality of projecting regions on the surface thereof. The first insulating film is provided on the projecting regions. The charge storage layer is provided on the first insulating film. The second insulating film is provided on the charge storage layer. The control gate electrode is provided on the second insulating film.

The semiconductor memory device of the present embodiment can increase a channel length of a memory cell transistor by including the above-described components. Therefore, a short channel effect of the memory cell transistor is suppressed. Therefore, a semiconductor memory device suppressing dispersion in threshold voltage variation is realized.

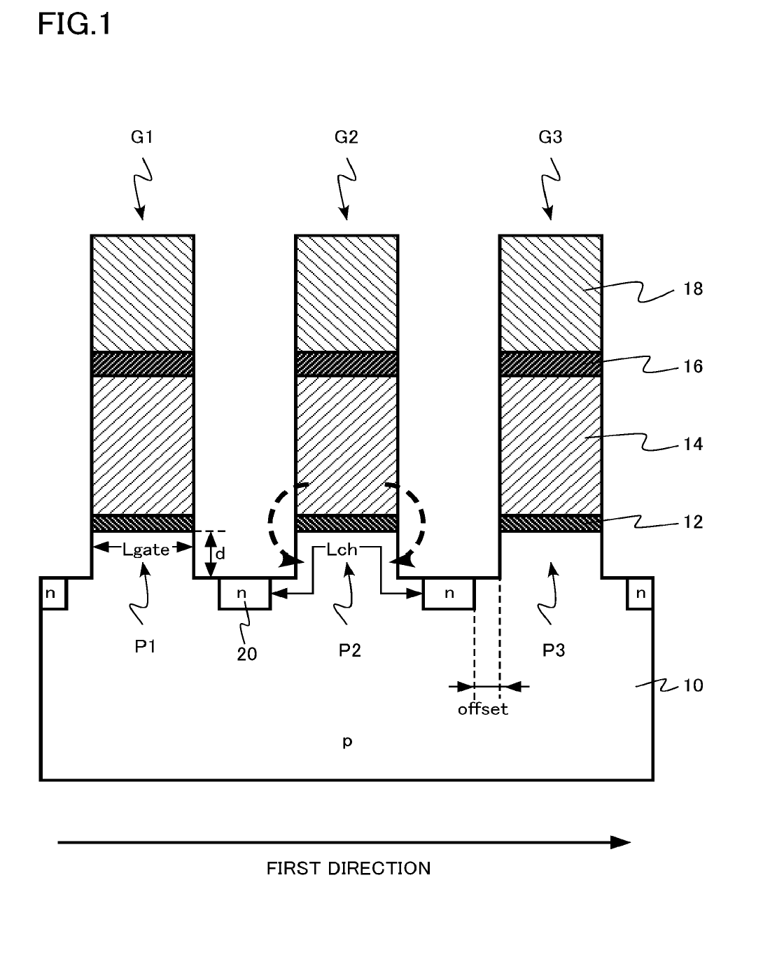

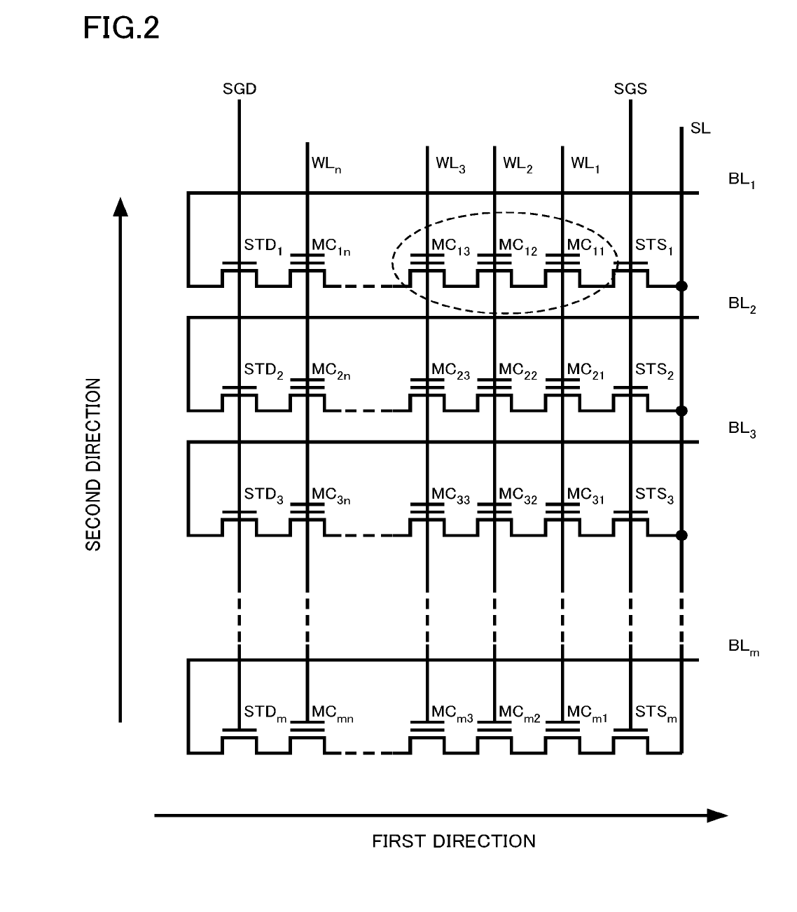

FIG. 1 is a schematic cross sectional view of a memory cell of the semiconductor memory device of the present embodiment. FIG. 2 is a circuit diagram of a memory cell array of the semiconductor memory device of the present embodiment. The semiconductor memory device of the present embodiment is a NAND type nonvolatile semiconductor memory device.

As illustrated in FIG. 2, for example, the memory cell array is constituted by memory cell transistors MC₁₁ to MC₁ₙ, MC₂₁ to MC₂ₙ, . . . , MCₘ₁ to MCₘₙ which are m×n (m, n: integer) transistors each having a floating gate structure. In the memory cell array, the memory cell transistors are arranged in a first direction and a second direction, and a plurality of memory cell transistors are thereby disposed in a matrix form.

In the memory cell array, for example, the memory cell transistors MC₁₁ to MC₁ₙ and select gate transistors STS₁ and STD₁ are connected in series to constitute a NAND string (memory string) which is a cell unit. The NAND string extends in the first direction.

A drain region of a select gate transistor STS₁ is connected to a source region of the memory cell transistor MC₁₁. The memory cell transistor MC₁₁ is positioned at an end of the arrangement of a group of memory cell transistors MC₁₁ to MC₁ₙ connected to each other in series. The select gate transistor STS₁ selects the memory cell transistors MC₁₁ to MC₁ₙ. A source region of the select gate transistor STD₁ is connected to a drain region of the memory cell transistor MC₁ₙ. The memory cell transistor MC₁, is positioned at an end of the arrangement of the group of memory cell transistors MC₁₁ to MC₁ₙ connected to each other in series. The select gate transistor STD₁ selects the memory cell transistors MC₁₁ to MC₁ₙ.

Select gate transistors STS₂ to STSₘ, the memory cell transistors MC₂₁ to MC₂ₙ, . . . , MCₘ₁ to MCₘₙ, and select gate transistors STD₂ to STDₘ are connected in series similarly, respectively, to constitute a NAND string.

A common source line SL is connected to a source of each of the select gate transistors STS₁ to STSₘ.

The memory cell transistors MC₁₁, MC₂₁, . . . , MCₘ₁, the memory cell transistors MC₁₂, MC₂₂, . . . , MCₘ₂, . . . , and the memory cell transistors MC₁ₙ, MC₂ₙ, . . . , MCₘₙ are connected through word lines WL₁ to WLₙ, respectively. The word lines WL₁ to WLₙ control an operating voltage applied to a control gate electrode.

In addition, a select gate line SGS and a select gate line SGD are included. The select gate line SGS is common to the select gate transistors STS₁ to STSₘ. The select gate line SGD is common to the select gate transistors STD₁ to STDₘ.

Peripheral circuits (not illustrated) are formed around the memory cell array in FIG. 2.

FIG. 1 illustrates cross sections of three memory cells in the memory cell array illustrated in FIG. 2, for example, of the memory cells MC₁₁, MC₁₂, and MC₁₃ surrounded by a dotted line in FIG. 2. In the present embodiment, a case in which the transistor of the memory cell is an n-type transistor using an electron as a carrier will be described as an example.

The semiconductor memory device of the present embodiment includes gate structures G1, G2, and G3 on a p-type semiconductor layer 10. Each of the gate structures G1, G2, and G3 includes a tunnel insulating film (first insulating film) 12, a floating gate (charge storage layer) 14, a block insulating film (second insulating film) 16, and a control gate 18. The semiconductor memory device includes an n-type impurity region 20.

The p-type semiconductor layer 10 extends in the first direction. An element isolation region (not illustrated) is provided in the second direction (a direction perpendicular to the paper surface in FIG. 1) of the p-type semiconductor layer 10. The first direction is preferably a <110> direction from a viewpoint of improving a mobility of the carrier of the memory cell transistor.

The p-type semiconductor layer 10 includes a plurality of projecting regions P1, P2, and P3 on the surface thereof. For example, the p-type semiconductor layer 10 is formed of silicon containing boron (B) as an impurity.

The gate structures G1, G2, and G3 are provided on the projecting regions P1, P2, and P3 of the p-type semiconductor layer 10, respectively. The width of each of the gate structures G1, G2, and G3 (“Lgate” in FIG. 1) is, for example, 10 nm or more and 30 nm or less. The width of each of the gate structures G1, G2, and G3 is preferably 15 nm or less. The space between the gate structures G1, G2, and G3 is, for example, 10 nm or more and 30 nm or less. The space between the gate structures G1, G2, and G3 is preferably 15 nm or less.

The tunnel insulating film 12 is provided on each of the projecting regions P1, P2, and P3 of the p-type semiconductor layer 10. An interface between the tunnel insulating film 12 and each of the projecting regions P1, P2, and P3 is substantially flat.

The tunnel insulating film 12 functions as a transportation path of an electron and a hole between the p-type semiconductor layer 10 and the floating gate 14 at the time of writing and erasing of the memory cell. The electron and the hole move in the tunnel insulating film 12 due to a tunneling phenomenon.

The tunnel insulating film 12 suppresses transportation of the electron and the hole between the p-type semiconductor layer 10 and the floating gate 14 at the time of reading and waiting of the memory cell. Barrier height of the tunnel insulating film 12 suppresses transportation of the electron and the hole.

The tunnel insulating film 12 is, for example, a silicon oxide film or a silicon oxynitride film. The tunnel insulating film 12 has a thickness, for example, of 5 nm or more and 15 nm or less.

The floating gate 14 is provided on the tunnel insulating film 12. The floating gate 14 functions as a charge storage layer. That is, the floating gate 14 positively stores a charge as memory cell information.

The floating gate 14 is, for example, formed of polycrystal silicon doped with impurities such as boron (B) or phosphorus (P). The floating gate 14 has a thickness, for example, of 40 nm or more and 70 nm or less.

The block insulating film 16 is provided on the floating gate 14. The block insulating film 16 is a so-called inter-electrode insulating film. The block insulating film 16 blocks flows of the electron and the hole between the floating gate 14 and the control gate 18.

The block insulating film 16 is, for example, a stacked film of a silicon oxide film and a silicon nitride film. The block insulating film 16 has a thickness, for example, of 10 nm or more and 30 nm or less.

The control gate 18 is provided on the block insulating film 16. The control gate 18 controls writing of charges to the floating gate 14 and reading of the charges of the floating gate 14.

The control gate 18 has, for example, a stacked structure of a metal and polycrystal silicon doped with impurities such as boron (B) or phosphorus (P). The metal is, for example, tungsten (W).

The n-type impurity region 20 is provided in each space between the projecting regions P1, P2, and P3 in the semiconductor layer 10. The n-type impurity region 20 functions as a source/drain region of a memory cell transistor. The n-type impurity region 20 includes, for example, arsenic (As) or phosphorus (P) as impurities.

The gate structures G1, G2, and G3 are preferably apart from the n-type impurity regions 20 in the first direction as illustrated by “offset” in FIG. 1. In other words, the floating gate 14 is preferably apart from the n-type impurity regions 20 in the first direction.

In the semiconductor memory device of the present embodiment, a trench 32 is formed in each space between the gate structures G1, G2, and G3 in the semiconductor layer 10. In other words, a first plane including an interface of the semiconductor layer 10 and the first insulating film 12 is closer to the gate electrode 18 than a second plane including the surface of the semiconductor layer 10 between the adjacent gate structures.

A distance between the interface between the tunnel insulating film 12 and each of the projecting regions P1, P2, and P3, and the lowest point of the surface between the projecting regions P1, P2, and P3 in a direction perpendicular to the above-described interface is referred to as d. A width (gate length) of each of the projecting regions P1, P2, and P3 is referred to as Lgate. It is preferable to satisfy 0.1×Lgate≦d≦Lgate.

It is more preferable to satisfy 0.2×Lgate≦d≦0.5×Lgate.

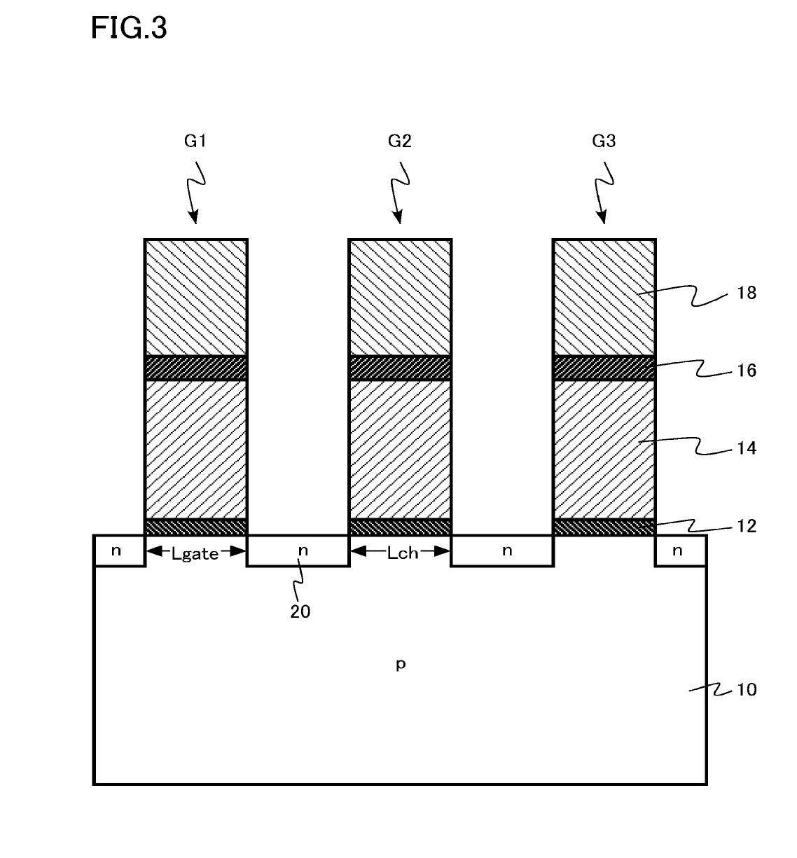

Hereinafter, functions and effects of the semiconductor memory device of the present embodiment will be described. FIG. 3 is a schematic cross sectional view of a memory cell of a semiconductor memory device of a comparative embodiment.

The memory cell of the comparative embodiment is similar to that in the present embodiment except that a trench is not formed in each space between the gate structures G1, G2, and G3 in the semiconductor layer 10.

As the memory cell is scaled down more, the gate length (“Lgate” in FIG. 3) of the memory cell transistor becomes shorter. As the gate length Lgate of the memory cell transistor becomes shorter, a length of a region where an inversion layer is formed during on-operation of the transistor, that is, a channel length (“Lch” in FIG. 3) also becomes shorter. The channel length Lch is, for example, a distance between the n-type impurity regions 20 sandwiching the gate structures G1, G2, and G3.

When the channel length becomes shorter, a short channel effect of the memory cell transistor becomes larger and a threshold voltage variation of the memory cell transistor becomes larger. When the threshold voltage variation of the memory cell transistor becomes larger, various failures such as read error of cell data are caused.

In the memory cell transistor of the semiconductor memory device of the present embodiment, a trench 32 is formed in each space between the gate structures G1, G2, and G3 in the semiconductor layer 10. The n-type impurity region 20 is provided at the bottom of the trench 32. In other words, the n-type impurity region 20 is not formed on a side surface of the trench 32 (side surfaces of the projecting regions P1, P2, and P3). The side surface of the trench 32 is a p-type region.

At the time of on-operation of the memory cell transistor, the p-type region on the side surface of the trench 32 is inversed by a fringe electric field (dotted line arrow in FIG. 1) going around the side surface of the trench 32 from the floating gate 14 to form an inversion layer.

Therefore, the channel length Lch of the memory cell transistor of the present embodiment is longer than the gate length Lgate. Therefore, for example, even when a memory cell transistor is formed with the same design rule as the comparative embodiment, a memory cell transistor having a longer channel length Lch than the comparative embodiment can be realized. Therefore, a memory cell transistor suppressing a short channel effect more than the comparative embodiment is realized. Therefore, a NAND type nonvolatile semiconductor memory device having a small threshold voltage variation of a memory cell transistor can be realized.

The gate structures G1, G2, and G3 are preferably apart from the n-type impurity regions 20 in the first direction as illustrated by “offset” in FIG. 1. The channel length Lch becomes longer, and the short channel effect is suppressed. The p-type region at the bottom of the trench 32 is also inversed by a fringe electric field going around the side surface of the trench 32 from the floating gate 14 to form an inversion layer.

A distance (depth of the trench 32) between the surface of each of the projecting regions P1, P2, and P3 and the lowest point of the surface between the projecting regions P1, P2, and P3 in a direction perpendicular to the interface between each of the projecting regions P1, P2, and P3 and the tunnel insulating film 12 is referred to as d. A width (gate length) of each of the projecting regions P1, P2, and P3 is referred to as Lgate. At this time, it is preferable to satisfy 0.1×Lgate≦d≦Lgate.

It is more preferable to satisfy 0.2×Lgate≦d≦0.5×Lgate.

When d is lower than the above-described range, it may be impossible to suppress the short channel effect sufficiently. When d is larger than the above-described range, the fringe electric field going around the side surface of the trench 32 from the floating gate 14 is weakened, and an inversion layer may not be formed on the side surface or the bottom of the trench 32.

Furthermore, in the semiconductor transistor of the present embodiment, a distance between the floating gate 14 and the semiconductor layer 10 between the gate structures G1, G2, and G3 is large. Therefore, a parasitic capacitance between the floating gate 14 and the semiconductor layer 10 is reduced. Therefore, a NAND type nonvolatile semiconductor memory device having a large operation margin of the memory cell can be realized.

According to the semiconductor memory device of the present embodiment, a NAND type nonvolatile semiconductor memory device suppressing the short channel effect of the memory cell transistor and having a small threshold voltage variation of the memory cell transistor can be realized. In addition, a NAND type nonvolatile semiconductor memory device having a large operation margin of the memory cell can be realized.

### Second Embodiment

A semiconductor memory device of the present embodiment is similar to that of the first embodiment except that a third insulating film having a larger dielectric constant than a first insulating film is provided between adjacent projecting regions. Therefore, some contents overlapping with the first embodiment are not described.

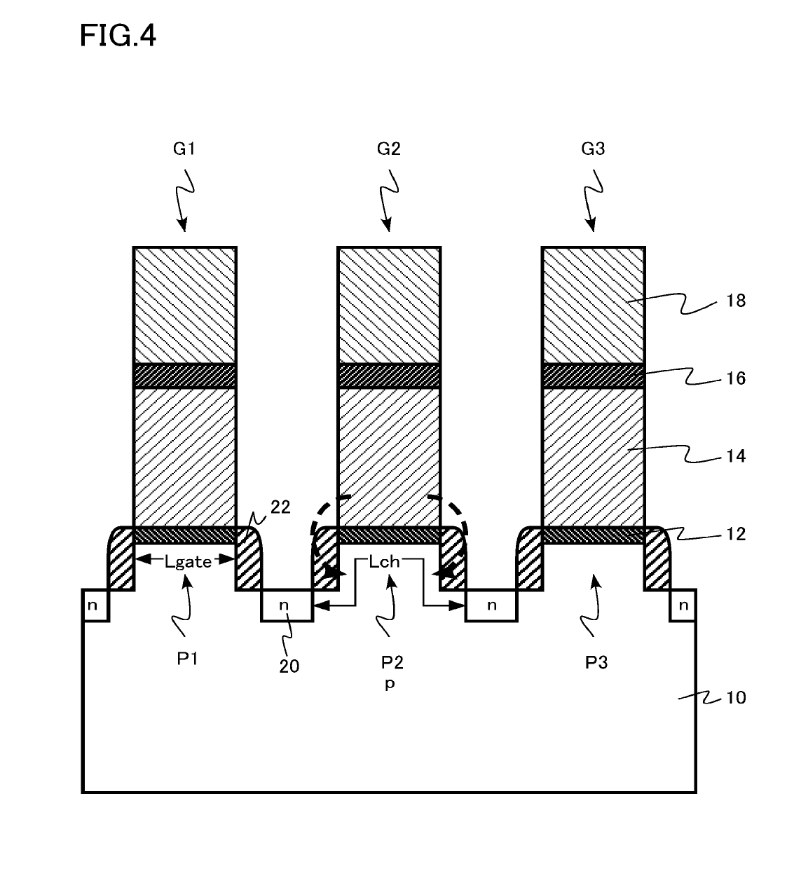

FIG. 4 is a schematic cross sectional view of a memory cell of the semiconductor memory device of the present embodiment.

As illustrated in FIG. 4, in a memory cell transistor of the semiconductor memory device of the present embodiment, a sidewall insulating film (third insulating film) 22 having a larger dielectric constant than a tunnel insulating film (first insulating film) 12 is provided between adjacent projecting regions P1, P2, and P3. In other words, the sidewall insulating film 22 having a larger dielectric constant than the tunnel insulating film 12 is provided in an area closer to a semiconductor layer 10 than an interface between the semiconductor layer 10 and the tunnel insulating film 12, between adjacent gate structures G1, G2, and G3. In other words, the sidewall insulating film 22 having a larger dielectric constant than the tunnel insulating film 12 is provided on a side surface of a trench 32.

For example, when the tunnel insulating film 12 is a silicon oxide film, the sidewall insulating film 22 is a silicon nitride film having a larger dielectric constant than the silicon oxide film.

According to the present embodiment, a fringe electric field going around the side surface of the trench 32 from a floating gate 14 is increased. Therefore, an inversion layer is easily formed by the floating gate 14. Therefore, it is easy to make a channel length Lch longer. Therefore, the memory cell transistor further suppressing the short channel effect is realized.

It is also possible to make a form in which the sidewall insulating film 22 is embedded between the adjacent projecting regions P1, P2, and P3.

According to the semiconductor memory device of the present embodiment, a NAND type nonvolatile semiconductor memory device suppressing the short channel effect of the memory cell transistor more and having a smaller threshold voltage variation of the memory cell transistor than the first embodiment, can be realized.

### Third Embodiment

A semiconductor memory device of the present embodiment is similar to that of the first embodiment except that a conductive layer is provided between adjacent projecting regions. Therefore, some contents overlapping with the first embodiment are not described.

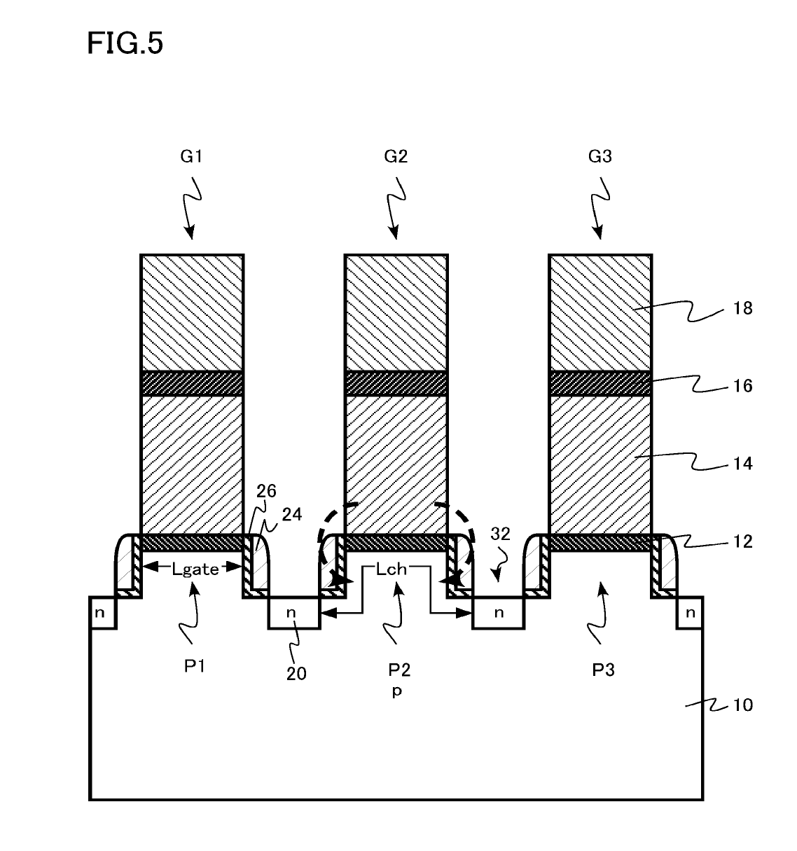

FIG. 5 is a schematic cross sectional view of a memory cell of the semiconductor memory device of the present embodiment.

As illustrated in FIG. 5, in a memory cell transistor of the semiconductor memory device of the present embodiment, a conductive layer 24 is provided between adjacent projecting regions P1, P2, and P3. In other words, the conductive layer 24 is provided in an area closer to a semiconductor layer 10 than an interface, between the semiconductor layer 10 and a tunnel insulating film 12 between adjacent gate structures G1, G2, and G3. In other words, the conductive layer 24 is provided on a side surface of a trench 32.

The conductive layer 24 is formed, for example, of polycrystal silicon doped with impurities such as boron (B) or phosphorus (P). An insulating film 26 is provided between the conductive layer 24 and the semiconductor layer 10. The insulating film 26 is, for example, a silicon oxide film.

According to the present embodiment, a fringe electric field going around the side surface of the trench 32 from a floating gate 14 is increased. Therefore, an inversion layer is easily formed by the floating gate 14. Therefore, it is easy to make a channel length Lch longer. Therefore, the memory cell transistor further suppressing the short channel effect is realized.

It is also possible to make a structure in which the conductive layer 24 is embedded between the adjacent projecting regions P1, P2, and P3.

According to the semiconductor memory device of the present embodiment, a NAND type nonvolatile semiconductor memory device suppressing the short channel effect of the memory cell transistor more and having a smaller threshold voltage variation of the memory cell transistor than the first embodiment, can be realized.

### Fourth Embodiment

A method for manufacturing a semiconductor memory device of the present embodiment includes forming a plurality of gate structures each including a first insulating film provided on a first conductivity type semiconductor layer extending in a first direction, a charge storage layer provided on the first insulating film, a second insulating film provided on the charge storage layer, and a control gate provided on the second insulating film, and etching the semiconductor layer using the gate structure as a mask to form a trench.

The method for manufacturing a semiconductor memory device of the present embodiment is one example of the method for manufacturing the semiconductor memory device of the first embodiment.

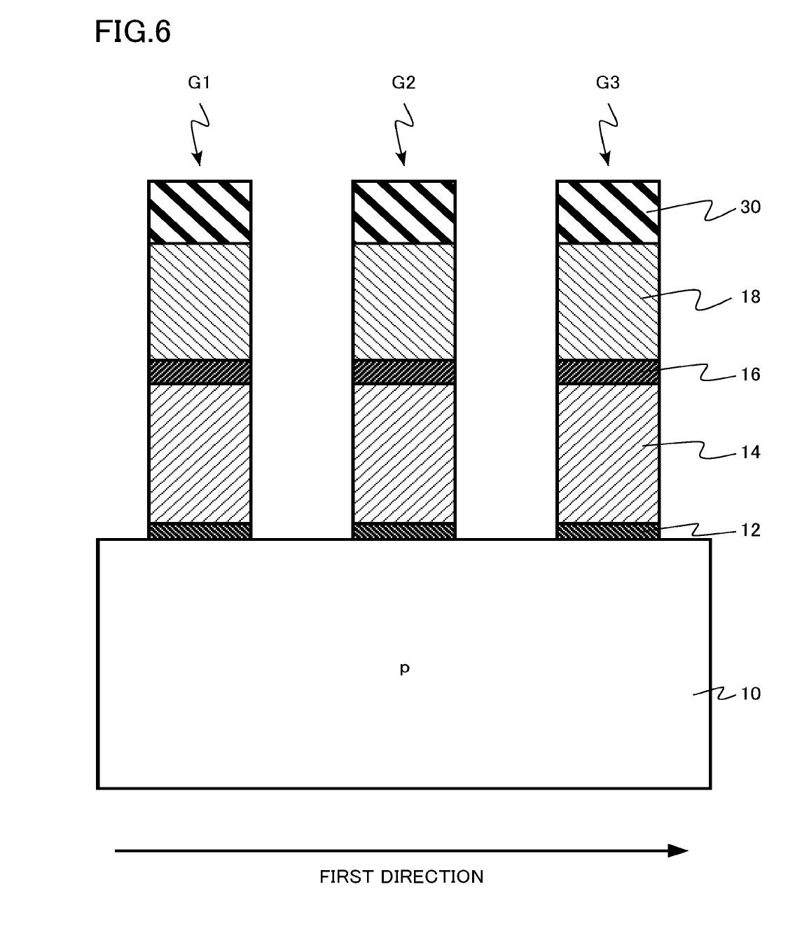

FIGS. 6, 7, and 8 are schematic cross sectional views of the semiconductor memory device during a manufacturing process in the manufacturing method of the present embodiment.

First, a plurality of gate structures G1, G2, and G3 to be provided on a p-type semiconductor layer 10 extending in a first direction are formed (FIG. 6). The plurality of gate structures G1, G2, and G3 are formed, for example, using a mask material 30 of a silicon oxide film as a mask. Each of the gate structures G1, G2, and G3 includes a tunnel insulating film (first insulating film) 12, a floating gate (charge storage layer) 14, a block insulating film (second insulating film) 16, and a control gate 18.

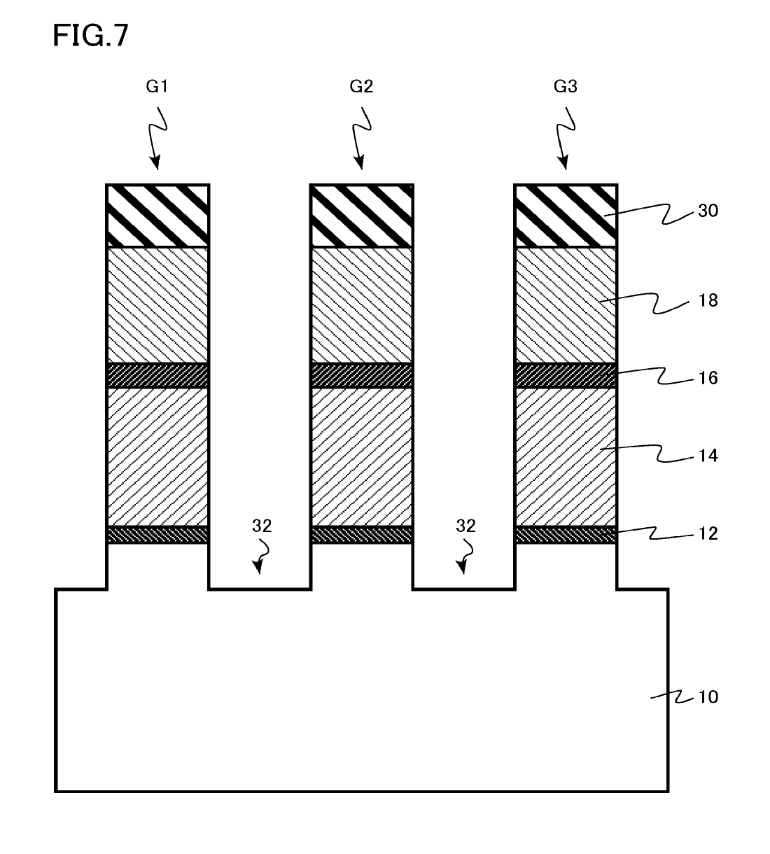

Subsequently, the semiconductor layer 10 is etched using the gate structures G1, G2, and G3 as a mask to form a trench 32 (FIG. 7). The trench 32 is formed, for example, by a RIE (Reactive Ion Etching) method.

When the trench 32 is formed, a depth from an interface between the semiconductor layer 10 at the lowest point of the trench 32 and the tunnel insulating film 12 is referred to as d, and a width of each of the gate structures G1, G2, and G3 is referred to as Lgate. At this time, it is preferable to satisfy 0.1×Lgate≦d≦Lgate.

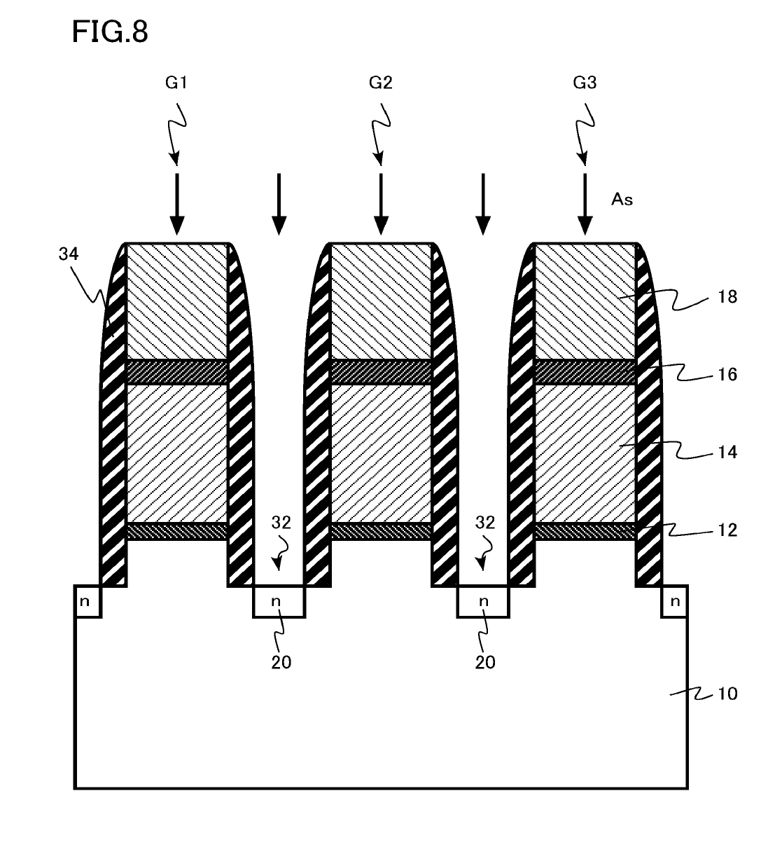

Subsequently, a sidewall 34 is formed on a side surface of the gate structures G1, G2, and G3. The sidewall 34 is, for example, a silicon oxide film. Subsequently, for example, ions of arsenic (As) are implanted into the semiconductor layer 10 at the bottom of the trench 32 using the gate structures G1, G2, and G3 and the sidewall 34 as a mask. By the ion implantation of arsenic (As), an n-type impurity region 20 is formed (FIG. 8).

Thereafter, the sidewall 34 is removed, for example, by wet etching. The semiconductor memory device illustrated in FIG. 1 is formed by the manufacturing method described above.

According to the method for manufacturing a semiconductor memory device of the present embodiment, a NAND type nonvolatile semiconductor memory device suppressing the short channel effect of a memory cell transistor and having a small threshold voltage variation of the memory cell transistor can be realized.

### Fifth Embodiment

A method for manufacturing a semiconductor memory device of the present embodiment includes forming a plurality of gate structures each including a first insulating film provided on a first conductivity type semiconductor layer extending in a first direction, a charge storage layer provided on the first insulating film, a second insulating film provided on the charge storage layer, and a control gate provided on the second insulating film, and implanting ions of oxygen into the semiconductor layer using the gate structure as a mask to form an oxide film by a heat treatment on the semiconductor layer into which the ions of oxygen have been implanted.

The method for manufacturing a semiconductor memory device of the present embodiment is one example of the method for manufacturing the semiconductor memory device of the first embodiment.

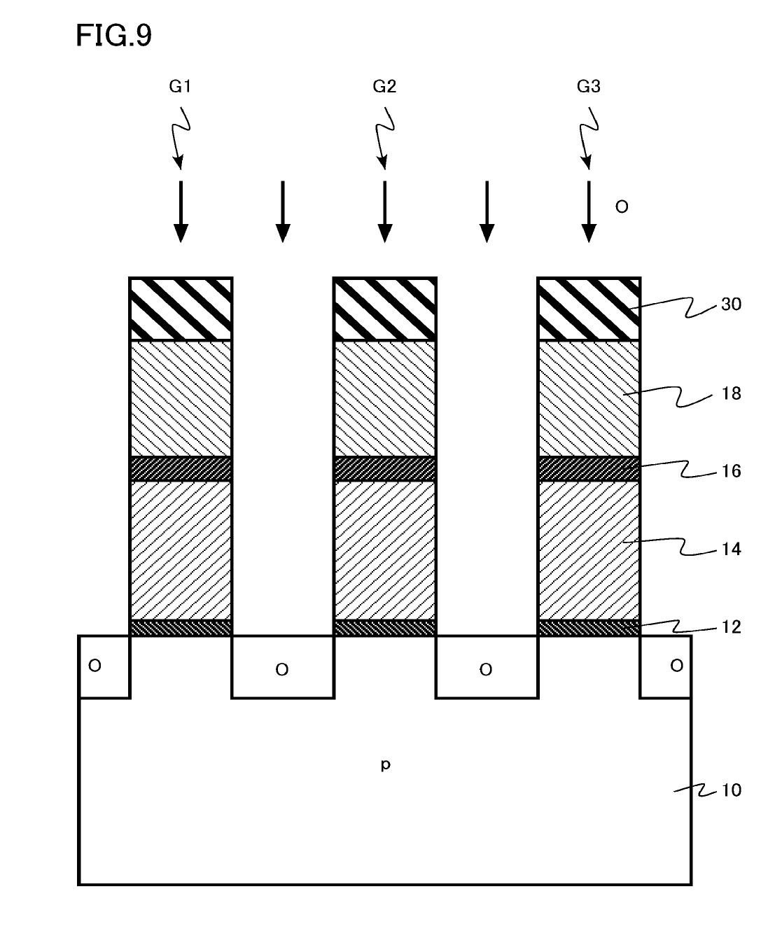

FIGS. 9, 10, and 11 are schematic cross sectional views of the semiconductor memory device during a manufacturing process in the manufacturing method of the present embodiment.

First, a plurality of gate structures G1, G2, and G3 to be provided on a p-type semiconductor layer 10 extending in the first direction are formed. The plurality of gate structures G1, G2, and G3 are formed, for example, using a mask material 30 of a silicon oxide film as a mask. Each of the gate structures G1, G2, and G3 includes a tunnel insulating film (first insulating film) 12, a floating gate (charge storage layer) 14, a block insulating film (second insulating film) 16, and a control gate 18.

Subsequently, ions of oxygen are implanted into the semiconductor layer 10 using the gate structures G1, G2, and G3 as a mask (FIG. 9).

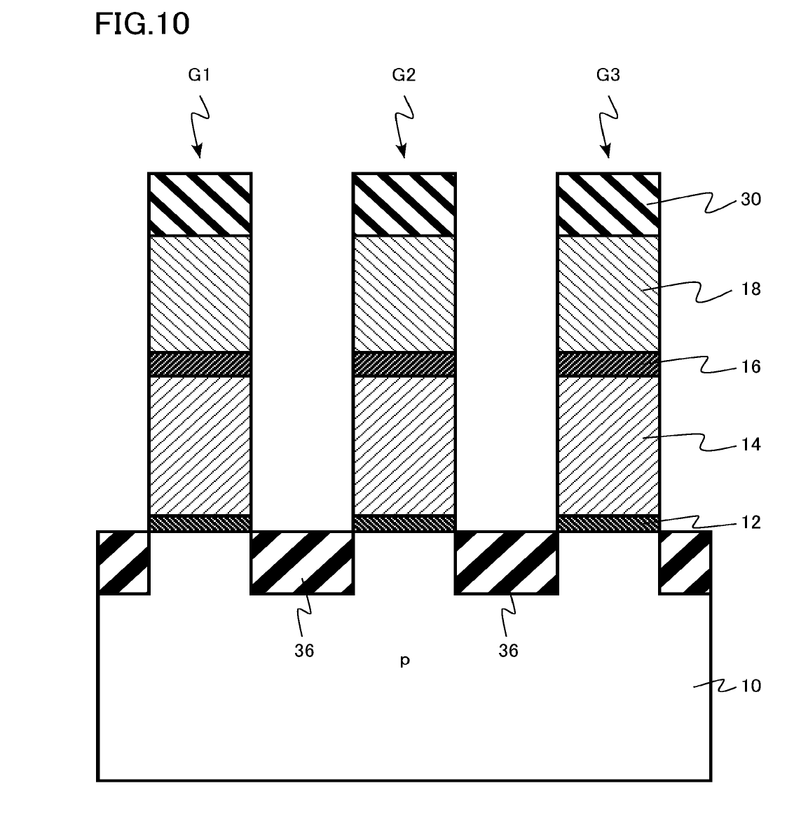

Subsequently, the heat treatment is performed in a non-oxidative atmosphere. An oxide film 36 is formed by this heat treatment on the semiconductor layer 10 into which the ions of oxygen have been implanted (FIG. 10). Oxidation of the gate structures G1, G2, and G3 is suppressed due to the heat treatment performed in the non-oxidative atmosphere.

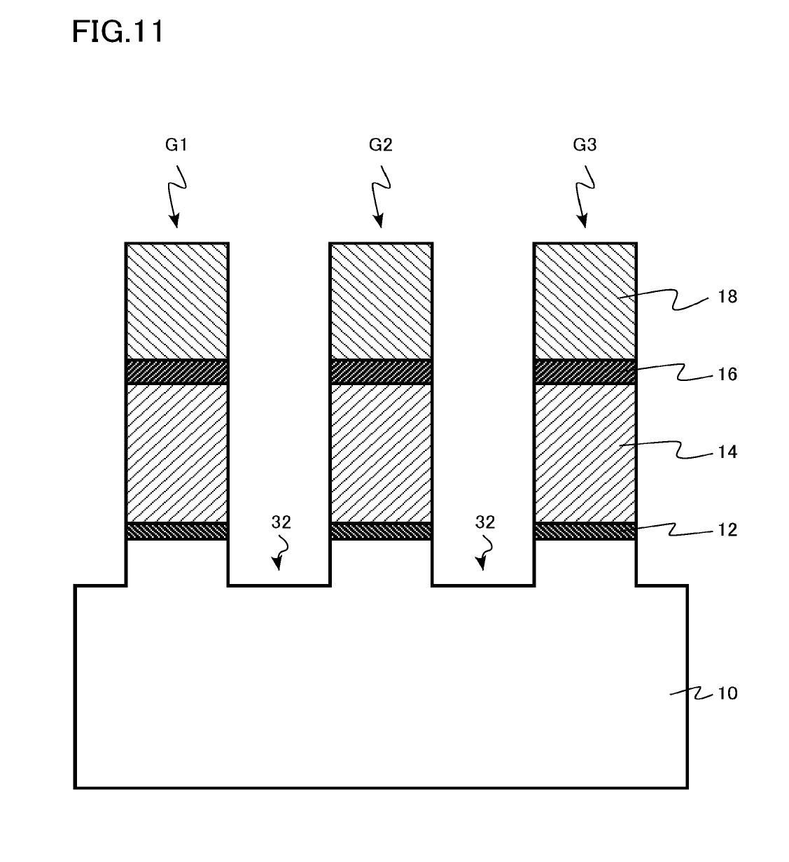

Subsequently, the oxide film 36 is removed to form a trench 32 (FIG. 11). The oxide film 36 is removed, for example, by the RIE method.

Thereafter, an n-type impurity region 20 is formed by a similar manner to the fourth embodiment. The semiconductor memory device illustrated in FIG. 1 is formed by the manufacturing method described above.

According to the method for manufacturing a semiconductor memory device of the present embodiment, a NAND type nonvolatile semiconductor memory device suppressing the short channel effect of a memory cell transistor and having a small threshold voltage variation of the memory cell transistor can be realized.

### Sixth Embodiment

A method for manufacturing a semiconductor memory device of the present embodiment includes forming a plurality of gate structures each including a first insulating film provided on a first conductivity type semiconductor layer extending in a first direction, a charge storage layer provided on the first insulating film, a second insulating film provided on the charge storage layer, and a control gate provided on the second insulating film, and forming a sidewall on a side surface of the gate structure to thermally oxidize the semiconductor layer.

The method for manufacturing a semiconductor memory device of the present embodiment is one example of the method for manufacturing the semiconductor memory device of the first embodiment.

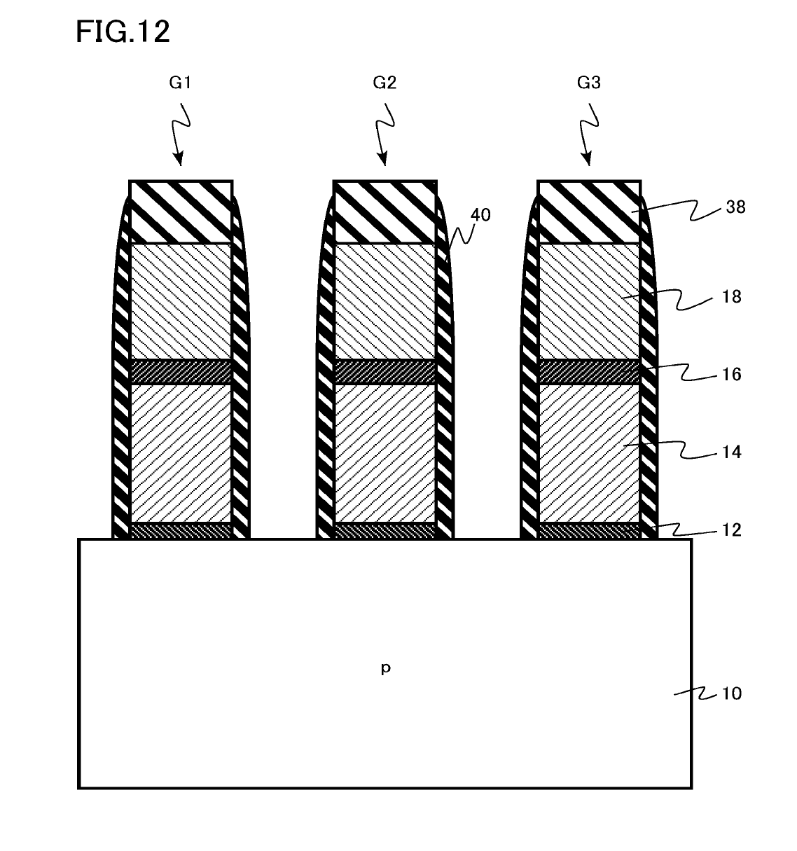

FIGS. 12, 13, and 14 are schematic cross sectional views of the semiconductor memory device during a manufacturing process in the manufacturing method of the present embodiment.

First, a plurality of gate structures G1, G2, and G3 to be provided on a p-type semiconductor layer 10 extending in the first direction are formed. The plurality of gate structures G1, G2, and G3 are formed, for example, using a mask material 38 of a silicon nitride film as a mask. Each of the gate structures G1, G2, and G3 includes a tunnel insulating film (first insulating film) 12, a floating gate (charge storage layer) 14, a block insulating film (second insulating film) 16, and a control gate 18.

Subsequently, sidewalls 40 are formed on side surfaces of the gate structures G1, G2, and G3 (FIG. 12). The sidewall 40 is, for example, a silicon nitride film.

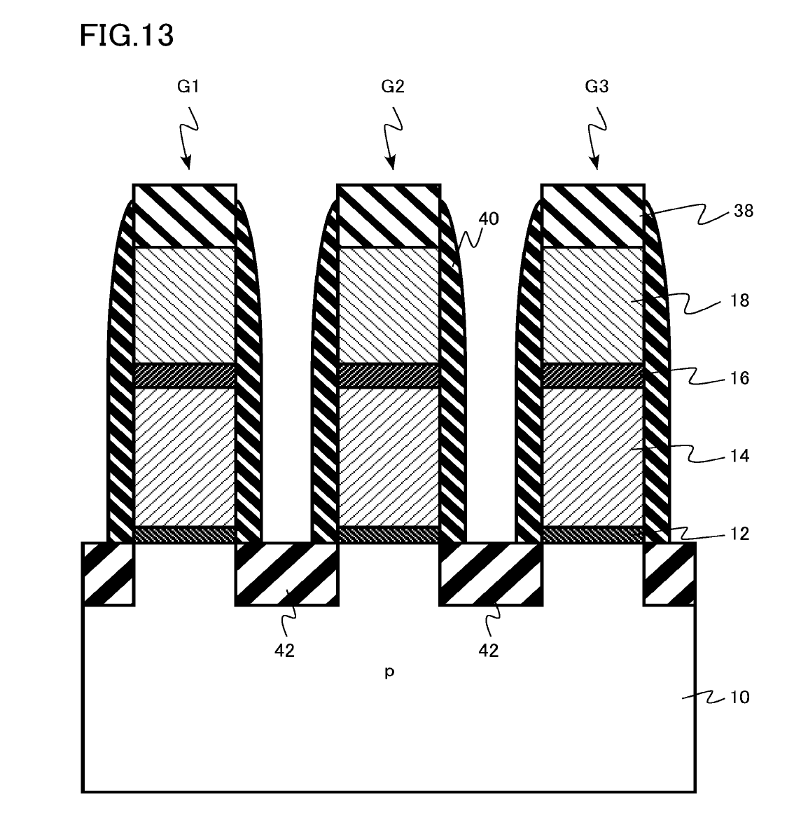

Subsequently, the semiconductor layer 10 is thermally oxidized in an oxidative atmosphere. A thermal oxide film 42 is formed selectively on the semiconductor layer 10 by the thermal oxidation (FIG. 13). The gate structures G1, G2, and G3 are prevented from being oxidized due to the mask material 38 and the sidewall 40.

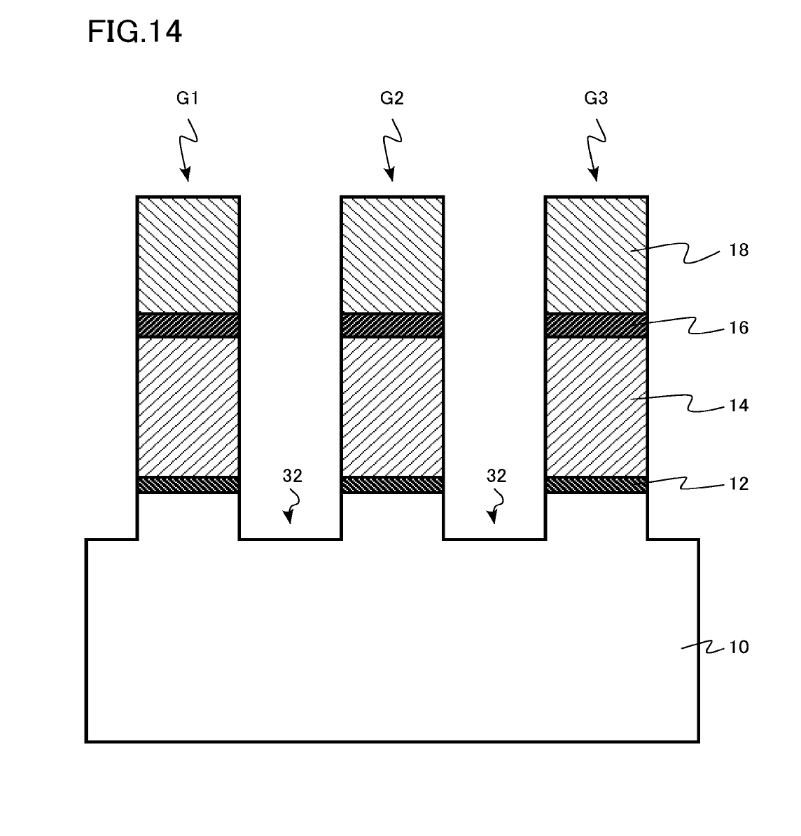

Subsequently, the mask material 38, the sidewall 40, and the thermal oxide film 42 are removed to form a trench 32 (FIG. 14).

Thereafter, an n-type impurity region 20 is formed by a similar manner to the fourth embodiment. The semiconductor memory device illustrated in FIG. 1 is formed by the manufacturing method described above.

According to the method for manufacturing a semiconductor memory device of the present embodiment, a NAND type nonvolatile semiconductor memory device suppressing the short channel effect of a memory cell transistor and having a small threshold voltage variation of the memory cell transistor can be realized.

In the first to sixth embodiments, as an example, polycrystal silicon which is a conductive layer has been described as the charge storage layer 14. However, it is also possible to use an insulating film as the charge storage layer 14. The insulating film is, for example, a silicon nitride film.

It is also possible to omit the n-type impurity region 20. In this case, the entire bottom of the trench 32 becomes an inversion layer inversed by a fringe electric field. Therefore, the channel length Lch becomes longer.

In the first to sixth embodiments, as an example, the side surface of the trench having a vertical shape has been described. However, the side surface of the trench can have a forwardly tapered shape or a reversely tapered shape.

In addition, as an example, the p-type first conductivity type semiconductor layer and the n-type second conductivity type semiconductor layer have been described. However, it is also possible to use an n-type first conductivity type semiconductor layer and a p-type second conductivity type semiconductor layer. In this case, the transistor of the memory cell is a p-type transistor using a hole as a carrier.

While certain embodiments have been described, these embodiments have been presented by way of example only, and are not intended to limit the scope of the inventions. Indeed, semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first conductivity type semiconductor layer extending in a first direction, the semiconductor layer having a plurality of projecting regions on a surface of the semiconductor layer;
a first insulating film provided on the projecting regions;
a charge storage layer provided on the first insulating film;
a second insulating film provided on the charge storage layer; and
a control gate provided on the second insulating film.

2. The semiconductor memory device according to claim 1, wherein
a second conductivity type semiconductor region is provided in the semiconductor layer, the semiconductor region is provided between adjacent projecting regions.

3. The semiconductor memory device according to claim 2, wherein
the charge storage layer is apart from the semiconductor region in the first direction.

4. The semiconductor memory device according to claim 1, wherein
an interface of the projecting region and the first insulating film is substantially flat.

5. The semiconductor memory device according to claim 1, wherein
when a distance between an interface of the projecting region and the first insulating film and the surface between the projecting regions in a direction perpendicular to the interface is referred to as d, and a width of the projecting region is referred to as Lgate, 0.1×Lgate≦d≦Lgate is satisfied.

6. The semiconductor memory device according to claim 1, wherein
the first direction is a <110> direction.

7. The semiconductor memory device according to claim 1, wherein
a third insulating film having a larger dielectric constant than the first insulating film is provided between the adjacent projecting regions.

8. The semiconductor memory device according to claim 1, wherein
a conductive layer is provided between the adjacent projecting regions.

9. A semiconductor memory device comprising:
a plurality of gate structures each including a first conductivity type semiconductor layer extending in a first direction, a first insulating film provided on the semiconductor layer, a charge storage layer provided on the first insulating film, a second insulating film provided on the charge storage layer, and a control gate provided on the second insulating film, wherein
a first plane including an interface of the semiconductor layer and the first insulating film is closer to the gate electrode than a second plane including the surface of the semiconductor layer between the adjacent gate structures.

10. The semiconductor memory device according to claim 9, wherein
a second conductivity type semiconductor region is provided in the semiconductor layer, the semiconductor region is provided between adjacent projecting regions.

11. The semiconductor memory device according to claim 10, wherein
the charge storage layer is apart from the semiconductor region in the first direction.

12. The semiconductor memory device according to claim 9, wherein
the interface is substantially flat.

13. The semiconductor memory device according to claim 9, wherein
when a distance between the interface and the surface in a direction perpendicular to the interface is referred to as d, and a width of the gate structure is referred to as Lgate, 0.1×Lgate≦d≦Lgate is satisfied.

14. The semiconductor memory device according to claim 9, wherein
the first direction is a <110> direction.

15. The semiconductor memory device according to claim 9, wherein
a third insulating film having a larger dielectric constant than the first insulating film is provided in an area closer to the semiconductor layer than the interface, between the adjacent gate structures.

16. The semiconductor memory device according to claim 9, wherein
a conductive layer is provided between the adjacent gate structures.

17. A method for manufacturing a semiconductor memory device, comprising:
forming a plurality of gate structures each including a first insulating film provided on a first conductivity type semiconductor layer extending in a first direction, a charge storage layer provided on the first insulating film, a second insulating film provided on the charge storage layer, and a control gate provided on the second insulating film, and
etching the semiconductor layer using the gate structure as a mask to form a trench.

18. The method for manufacturing a semiconductor memory device according to claim 17, wherein
when a depth of the trench from an interface of the semiconductor layer and the first insulating film is referred to as d, and a width of the gate structure is referred to as Lgate, 0.1×Lgate≦d≦Lgate is satisfied.

19. The method for manufacturing a semiconductor memory device according to claim 17, wherein
a second conductivity type semiconductor region is formed by ion implantation into the semiconductor layer at the bottom of the trench after the trench is formed.

20. The method for manufacturing a semiconductor memory device according to claim 19, wherein
a sidewall is formed on a side surface of the gate structure before the ion implantation.
